(19) United States
(12) Patent Application Publication
(10) Pub. No.: US 2004/0022400 A1
(43) Pub. Date: Feb. 5, 2004

(54) Bass compressor

(76) Inventor: Anthony J. Magrath, Edinburgh (GB)

Correspondence Address: DICKSTEIN SHAPIRO MORIN & OSHINSKY LLP, 2101 L STREET NW, WASHINGTON, DC, 20037-1526, US

(21) Appl. No.: 10/214,641

(22) Filed: Aug. 9, 2002

(30) Foreign Application Priority Data
Jul. 30, 2002 (GB) 0217639.4

(51) Int. Cl. H03G 5/00; H03G 7/00

(52) U.S. Cl. 381/106; 381/98

(57) ABSTRACT

This invention generally relates to audio signal processing apparatus and methods for altering, and particularly increasing, the perceived level of bass frequencies in an audio signal. The apparatus comprises an audio input (202) to receive an audio input signal; a compressor (204) coupled to the audio input and having an output, to compress said audio input signal; a high-cut filter coupled to the output of said compressor to provide a filtered compressor output; and a combiner (206) to combine a signal from said compressor output with a signal from said audio input to provide a combined audio output; and wherein said compressor is configured to distort said audio input signal such that said distortion is perceivable as an increase in the level of bass in said combined audio output.

### FIELD OF THE INVENTION

This invention generally relates to audio signal processing. More particularly it relates to apparatus and methods for altering, and particularly increasing, the perceived level of bass frequencies in an audio signal.

### BACKGROUND TO THE INVENTION

The bass response of many low-cost headphones and loudspeakers, as well as mid-fidelity audio systems, particularly portable systems, is often relatively poor. However listeners frequently desire an enhanced bass component, particularly when listening to music with a strong beat. For this reason many bass boost circuits have been proposed, such as those described in U.S. Pat. No. 5,481,617, U.S. Pat. No. 4,055,818, U.S. Pat. No.5,509,080, EP 0 266 148A and DE 197 42 803A.

FIG. 1 shows a conventional bass boost/cut circuit 100, which may be implemented in either the analogue or the digital domain, or in a combination of the two. An audio input signal on line 102 is provided to a low-pass filter 104 and to an output adder or combiner 106. Low-pass filter 104 passes only that range of frequencies which it is desired to boost, for example frequencies below 100 Hz. An output from low-pass filter 104 is amplified by a gain block 108 and then added to the original input signal in combiner 106 to provide a bass boosted output 110.

The level of bass boost is controlled by the gain, G, of gain block 108, and by choosing G<0, that is by inverting the input to adder 106 so that the bass boosted signal is effectively subtracted, a bass cut function can be provided. An attenuator may be provided before bass boost circuit 100 to provide some signal headroom so that the bass can be boosted without limiting occurring.

A problem with bass boost circuits implemented in the digital domain is that overload occurs when the bass signal exceeds the dynamic range of the digital word, and this limits the amount of bass boost that can be applied. This problem is solved in the prior art by attenuating the whole signal prior to applying a bass boost function, but this technique suffers from the disadvantage of reducing the dynamic range of the signal, resulting in a lower signal-to-noise ratio. Furthermore where a digital-to-analogue converter is employed maximum voltage swings at the output of the digital-to-analogue converter are reduced, although compensation for such attenuation may be provided in the form of increased analogue gain following the digital-to-analogue converter. Another technique for avoiding overload is described in U.S. Pat. No. 5,255,324, which senses clipping in a power amplifier and reduces narrowband bass boost gain in response.

Bass boost circuits may include a so-called loudness equalisation function, which compensates for the fact that at low amplitudes the human ear is less sensitive to low frequencies than to higher frequencies. This is described, for example, in Tomlinson Holman and Frank S. Kapmann, “Loudness Compensation: Use and Abuse”, 58^{th} AES Convention, Nov. 4-7, 1977 and WO 02/21687, and an improved automatic loudness compensation arrangement which reduces the undesirable effects of boominess in the reproduction of voices which can occur is described in U.S. Pat. No. 4,739,514. Loudness functions generally link the level of bass boost to the overall volume control setting, to provide more bass boost at low volumes, but this function does not take into account the dependence of the amplitude of bass signals upon the audio programme material as well as upon the overall volume.

Another technique is to use a harmonics generator to create the illusion that the audio includes lower frequency signals than in fact are present. Such techniques are described in U.S. Pat. No. 6,134,330, WO 98/46044, WO 97/42789 and Danael Ben-Tzur and Martin Colloms, “The effect of MaxBass Psychoacoustic Bass Enhancement on Loudspeaker Design”, ABS 106^{th} Convention, Preprint 4892, May 1999. The harmonics may be created by distorting the signal using a non-linear element such as a diode or integrating rectifier. The human ear is relatively insensitive to distortion at low frequencies and the added harmonics are perceived as an increase in the level of bass frequencies although these are not in fact present in the signal. The underlying principle has been used in church organs for more than 200 years, a 5⅓ foot stop reinforcing the bass one octave below the pitch of the actual note, that is the 16-foot bass, and a 10⅔ foot stop creating the effect of 32-foot pipes. The aim of these techniques is to increase the perceived bass level without in fact boosting bass components of the signal, to avoid the distortion or even damage to a loudspeaker which could otherwise occur.

A further technique for bass enhancement is to create sub-harmonics of an input signal, for example by clipping the input signal and then dividing by two, to add an actual bass component to the signal which was not originally present. Such a technique is described in US 2001/0036285A.

The technique of companding is known in the context of audio systems for increasing the signal-to-noise ratio (SNR) of an audio signal without distortion. The SNR of a system may be improved by amplification of a signal prior to its transmission through a noisy channel, but such amplification is limited by distortion of the channel at high signal levels. A solution to this problem is to compress the dynamic range of the signal prior to transmission over the channel and then afterwards to expand the dynamic range once again to reduce the noise level, hence “companding”. Probably the best known example is the Dolby (Trade Mark) system for tape recording as described, for example, in R. Dolby “An Audio Noise Reduction System”, J. Audio Eng. Soc., Vol. 15 (4), October 1967 and later developed, for example, in U.S. Pat. No. 3,846,719 and U.S. Pat. No. 3,934,190. As the skilled person will know, generally speaking a compressor has a gain which is varied in response to signal level, typically using RMS (Root Mean Square) signal level detection with an associated time constant. An essential feature of the Dolby system is that it operates on a syllabic timescale rather than controlling the gain in response to instantaneous signal level. However instantaneous companding is known, for example for applying a claw or A-law to PCM (Pulse Code Modulation) data. An example of a digital compander is described in EP 0 394 976A.

Prior art digital companding systems go to great lengths in order to achieve high linearity and low distortion. An exemplary system is described in G. W. McNally, “Dynamic Range Control of Digital Audio Signals”, J. Audio Eng. Soc., Vol. 32, No. 5, May 1984, which uses a level detector to determine the average or peak amplitude of an input signal, linear-to-logarithmic conversion and compression curve tables to determine a gain to apply, and a multiplier to apply this gain. Audio signal compression is sometimes employed without a corresponding signal expansion in specialized applications, for example bearing aids as described in U.S. Pat. No. 4,882,762.

The above-described prior art bass boost arrangements are useful for increasing the perceived level of bass frequencies in an audio signal but it is nonetheless desirable to still further increase the perceived level of bass in particular, in the context of digital audio, without causing overload and hard-limiting of the digital signal. The present invention addresses this problem.

### SUMMARY OF INVENTION

According to a first aspect of the present invention there is therefore provided an audio input to receive an audio input signal; a compressor coupled to the audio input and having an output, to compress said audio input signal; a high-cut filter coupled to the output of said compressor to provide a filtered compressor output; and a combiner to combine a signal from said compressor output with a signal from said audio input to provide a combined audio output; and wherein said compressor is configured to distort said audio input signal such that said distortion is perceivable as an increase in the level of bass in said combined audio output.

Employing a compressor to distort the audio input signal allows an enhanced increase in the energy of bass frequencies in the signal without overload. Furthermore because the arrangement boosts low-amplitude signals more than higher amplitude signals an automatic loudness equalisation function is effectively also provided. Furthermore the non-linear compressor may be implemented in a relatively simple and inexpensive manner, the added lower frequency harmonics being perceived as an increase in bass level rather than as distortion per se.

The apparatus includes a high-cut, or equivalently low-pass, filter between the output of the compressor and the combiner in order to attenuate higher than bass frequencies, in particular higher frequency harmonics introduced by the compressor and thus reduce any residual audible distortion. There is no need to remove such higher than bass frequencies entirely. The impression of bass boost may be varied to some extent by varying the cut-off characteristics (for example, the 3 dB cut-off frequency and roll-off) of the high cut/low-pass filter. The skilled person will recognise that in the context of this invention a precise definition of what constitutes a bass frequency is not important, although generally such frequencies may be considered to comprise frequencies of less than 100 Hz.

Preferably the compressor is a substantially instantaneous compressor, for example altering the compressor gain substantially instantaneously in response to instantaneous digitised input signal levels. This simplifies overload prevention and facilitates substantially instantaneous modification of the audio input signal levels to introduce the desired distortion. In other words, by applying an instantaneous, non-linear compression function the audio input signal can be mapped into a distorted version of the input signal to create the desired impression of an increase in the energy of the bass frequencies.

In one embodiment the instantaneous compressor gain is dependent upon a substantially instantaneous (for example, digital) level of signal input to the compressor. This compressor gain may have one or more step changes dependent upon the instantaneous signal level input, and in a digital system such an arrangement may be simply implemented by means of a left-shift operation. Thus the compressor may comprise a gain selector and a multiplier, such as a left-shifter, responsive to the gain selector. The gain selector may comprise a most significant bit (MSB) detector to detect a most significant bit of a digital audio input to the compressor and, optionally, may include a divider, such as a right-shifter, to control a compression factor for the compressor. Advantageously the gain selector, including the MSB detector and divider/right shifter, may be implemented as a look-up table in ROM (Read Only Memory).

In a preferred embodiment the apparatus further comprises an arrangement to detect the occurrence of a high signal level, for example a signal level which may lead to overload, and in response perform a signal attenuation or limiting function with the aim of preventing signal overload within the apparatus. In a digital system this function has the aim of preventing a digital signal level reaching a hard limit imposed by the finite number of bits used to represent such a digital signal.

In another aspect the invention provides a non-linear, instantaneous digital compressor comprising an input; a gain selector coupled to said input; and a variable left shifter coupled to said input and responsive to said gain selector to apply a variable gain to a digital signal on said input responsive to an instantaneous level of said digital signal.

A digital compressor of this type can be advantageously employed with the above-described apparatus for altering the perceived level of bass in an audio signal, and can be implemented simply and cheaply.

In a further, related aspect the invention provides a method of altering a perceived level of bass in an audio signal, the method comprising compressing and distorting the audio signal to provide a compressed and distorted signal in which the distortion is perceivable as an increase in the level of bass of the signal; low-pass filtering said compressed and distorted signal; and combining said audio signal with said filtered compressed and distorted signal to provide an output signal with an altered perceived level of bass.

The invention further provides processor control code, and a carrier medium carrying the code, to implement the above-described apparatus, method, and compressor. The code may comprise conventional programme code or microcode or code for configuring and/or controlling an ASIC or FPGA, or other similar code. The carrier may comprise any conventional storage medium such as a disk or CD- or DVD-ROM, or programmed memory such as ROM, or a data carrier such as an optical or electrical signal carrier. As the skilled person will appreciate the code may be distributed between a plurality of coupled components in communication with one another.

### BRIEF DESCRIPTION OF THE DRAWINGS

Preferred embodiments of the invention will now be described, by way of example only, with reference to the accompanying figures in which:

FIG. 1 shows a known bass boost/cut circuit;

FIG. 2 shows a bass compressor according to an embodiment of the present invention;

FIGS. 3a to 3c show, respectively, a compressor, a gain selector, and a most significant bit detector for the bass compressor of FIG. 2;

FIGS. 4a and 4b show a DC transfer function for the compressor of FIG. 3a on, respectively, a linear scale and a logarithmic scale;

FIG. 5 shows a transfer function for the compressor of FIG. 3a followed by a low-pass filter; and

FIG. 6 shows an input signal to the compressor of FIG. 3a and an output signal from the compressor of FIG. 3a.

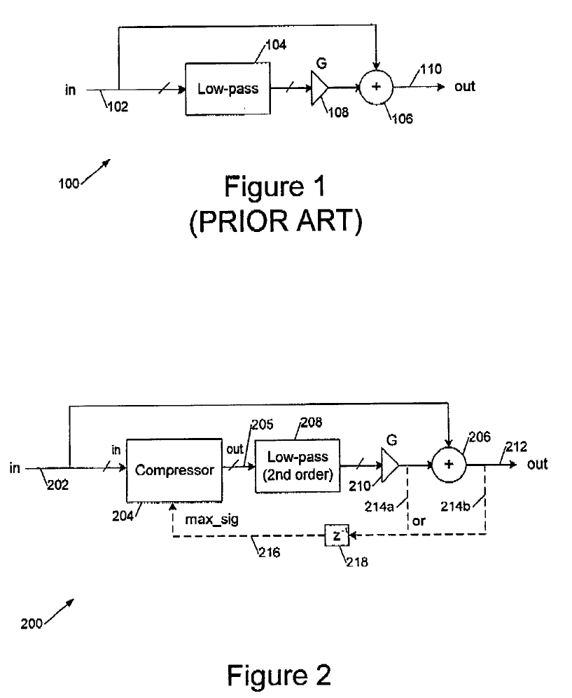

### DETAILED DESCRIPTION OF THE PREFERRED EMBODIMENTS

FIG. 2 shows a bass compressor circuit 200 embodying an aspect of the present invention. In a preferred embodiment bass compressor 200 is implemented in the digital domain, and may thus be implemented either in dedicated digital hardware or using a digital signal processor (DSP), or both.

In outline, a digital audio input signal is provided to a non-linear, instantaneous compressor circuit which shifts each digital word to the left by an amount that depends upon the amplitude of the word. This distorts the output of the compressor and the distorted output is low-pass filtered to attenuate higher frequency harmonics, amplified by a gain factor, and added to the input signal. The gain factor controls the level of bass in the output signal. Residual distortion present in the signal occurs predominantly at low frequencies and in many applications is scarcely audible to the human ear.

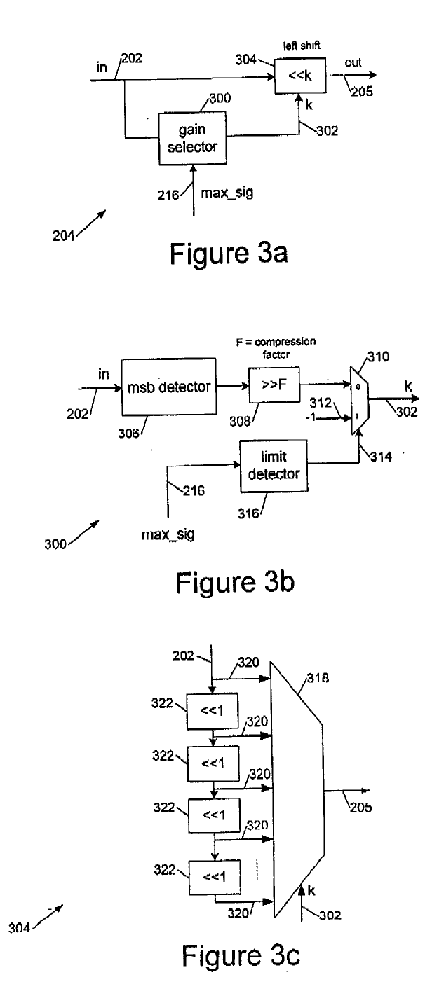

In more detail, a digital audio input bus 202 provides a digital audio signal to a compressor 204 and to a combiner 206. The output of the compressor 204 is filtered by a digital low-pass filter 208, which preferably has a second order roll-off (12 dB per octave). The output from low-pass filter 208 is provided to a gain block 210 which, in turn, provides a second input to combiner 206. In a preferred embodiment combiner 206 sums these two input signals and provides a combined output on line (or bus) 212, Optionally a feedback path shown by dashed lines 214a, b and 216 may be included to provide overload detection. The feedback may be taken either from the output of gain block 210, as indicated by dashed line 214a, or from the output of combiner 206, as indicated by dashed line 214b. The feedback provides a signal on line 216 to compressor 204 for detecting a maximum permitted signal level. In a digital implementation the feedback loop includes a one sample delay 218, for causality. FIGS. 3a and 3b show implementations of the compressor and of a gain selector for the compressor, respectively. Referring to FIG. 3a, the compressor 204 is implemented as a gain selector 300 coupled to input 202, in combination with a power-of-two gain block 304, implemented as a left shift operation. The gain selector 300 determines the instantaneous gain of the compressor based upon an instantaneous signal level on input 202, and provides an output k on line 302 for controlling variable gain block 304. The output of the compressor is provided on line 205.

FIG. 3b shows an implementation of the gain selector 300, comprising a most significant bit (MSB) detector 306 coupled to input line 202 and providing an output to a compression factor (F) determining module 308. Module 308 is preferably implemented as a power-of-two gain block using a right shift operation. The output of compression factor module 308 provides a value of k on line 302 via a multiplexer 310.

In a preferred embodiment the MSB detector 306 and right shift compression factor module 308 are implemented as a look-up table in ROM which is configured to provide direct mapping between an input word on line 202 and a value of k for output on line 302. Alternatively MSB detector 306 may be implemented using combinatorial logic.

Multiplexer 310 is optional but may be employed to provide an overload control function. Multiplexer 310 has two inputs, one from compression factor module 308 and a second input 312 set at a fixed or flag value, in the illustrated embodiment, −1, corresponding to a reduction in gain in block 304 by 6 dB (one night shift with sign extension). Selection of one of the two inputs is controlled by an output 314 from a limit detector 316 which is coupled to compressor control line 216. When a maximum permitted (positive or negative) signal is provided on line 216 limiting detector 316 controls multiplexer 310 to provide a signal to gain block 304 to attenuate the output of the compressor. The limit detector 316 may be implemented by combinatorial logic operating on a plurality of the most significant bits of the signal on line 216, for example to detect, in 2's complement fixed point notation, a value of 0.1XXX . . . (a value>=0.5 in decimal or a value of 1.0XXX . . . (a value<−0.5 in decimal).

FIG. 3c shows one implementation of a variable left shift function for gain block 304. This comprises a multiplexer 318 with multiple inputs 320 each receiving a successively left-shifted version of the input signal on line 202, provided by 1-bit left shifters 322. Multiplexer 318 selects an appropriately shifted version of the input signal according to a value k on control input 302.

The gain selector has two modes of operation, a normal mode and a limiting mode. The normal mode of operation will be described first.

In the normal mode of operation MSB detector 306 determines a coarse approximation to the input signal level on line 202 by establishing the highest bit that is set in the input word. In one embodiment MSB detector 306 is implemented using an absolute value calculation followed by a look-up table, although in other embodiments other implementations may be employed. The output of the MSB detector 306 is, in the presently described embodiment, an integer value which increases as the MSB becomes less significant. The output from MSB detector 306 is “divided” by the compression factor F by means of a right shift (strictly speaking this value is divided by 2^{F}). The resulting output from compression factor module 308 provides the output of the gain selector 300 in normal mode and is used to control the gain (i.e. left shift) of compressor 204.

An example of this normal mode of the compressor's operation is given in Table 1 below:

TABLE 1

| Input Word absolute value | MSB detector | >>F output | Compressor output |
|---|---|---|---|
| (binary) | output | (F = 1) | (positive signals) |
| 1.XXXXXXXXXXXXXX | 0 | 0 | 1.XXXXXXXXXXXXXX |
| 0.1XXXXXXXXXXXXX | 1 | 0 | 0.1XXXXXXXXXXXXX |
| 0.01XXXXXXXXXXXX | 2 | 1 | 0.1XXXXXXXXXXXX |
| 0.001XXXXXXXXXXX | 3 | 1 | 0.01XXXXXXXXXXX |
| 0.0001XXXXXXXXXX | 4 | 2 | 0.01XXXXXXXXXX |
| 0.00001XXXXXXXXX | 5 | 2 | 0.001XXXXXXXXX |
| etc | etc | etc | etc |

Referring to Table 1, the absolute value of the input word has a binary fixed point notation as shown. The output of MSB detector 306 comprises a series of integer values which, when right shifted by one bit position (since in this example F=1), result in the values in the third column of the table. The input word is then left shifted by the output of compression factor module 308 to provide the compressor output shown in the rightmost column of the table, also in binary fixed point notation (for clarity, in this example, assuming positive signals). It can be seen that with F=1 compressor 204, amplifies the input signal on line 202 by half the value from the MSB detector 306, resulting in a compression factor of 2:1. Larger values of F give lower levels of compression.

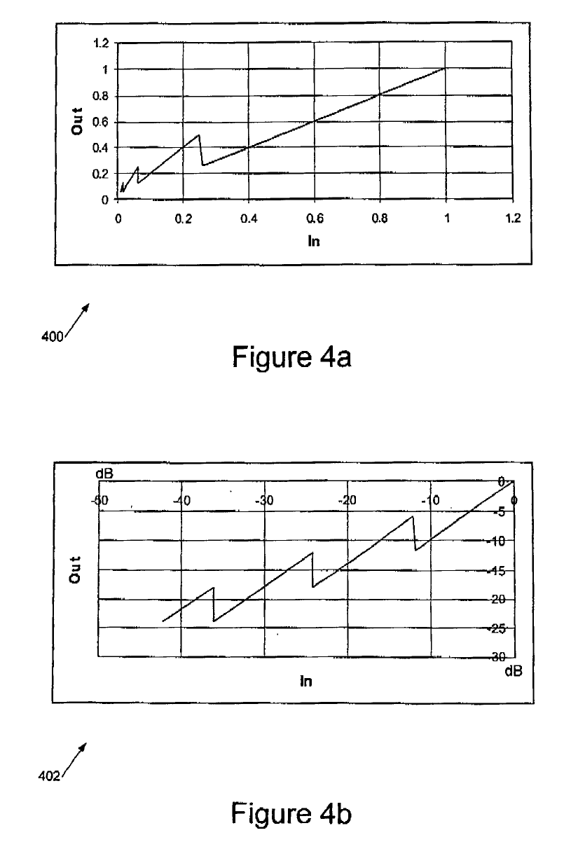

The normal mode operation of compressor 204 provides a transfer function as illustrated in FIGS. 4a and 4b. FIG. 4a shows a DC transfer function 400 for compressor 204 on a linear scale, with the input signal to the compressor on the x-axis and the output signal from the compressor on the y-axis. The quadrant of the graph of FIG. 4a where the input and output signals of the transfer function are both negative is not shown in the Figure but is a reflection of the illustrated curve through the origin. FIG. 4b shows a logarithmic presentation 402 of the same transfer function, with the input signal in dB on the x-axis and the output signal in dB on the y-axis so that the point (0,0) on/FIG. 4b corresponds to the point (1,1) on FIG. 4a. Since the input and output signals are voltages their values in dB are given by 20 log₁₀ (signal).

Referring to FIG. 4a it can be seen, for example, that there is a step reduction in gain of the compressor at an input signal level of 0.25, that is 0.01 in binary fixed point notation. This corresponds to a step change in the signal on output k 302 controlling left-shifter 304. Another step change in the compressor gain occurs at a floating point binary input word absolute value of 0.001, as can also be seen by inspection of Table 1. In a corresponding manner there are additional step changes in gain as the input signal level reduces further.

FIG. 4b illustrates that on a log-log scale the transfer function of compressor 204 is generally linear but with a superimposed sawtooth pattern. This is because the coarse approximations used in the compressor 204 introduce discontinuities in the transfer function.

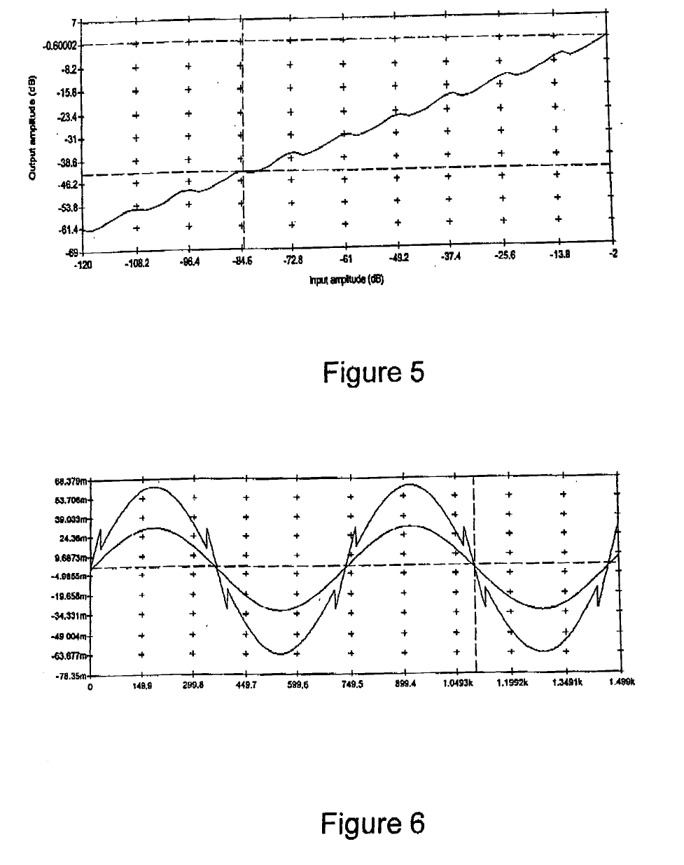

FIG. 5 shows a transfer function for a combination of compressor 204 and low-pass filter 208, that is from the input of the compressor to the output of the low-pass filter, for an 80 Hz sinewave input to the compressor and a 120 Hz filter cutoff frequency. The amplitude of the fundamental (80 Hz) input signal input signal to compressor 204 in dB is on the x-axis and on the y-axis is plotted amplitude of the fundamental frequency of the output from low-pass filter 208, in dB.

The transfer function shown in FIG. 5 is only that of the fundamental component of the input sinewave that is the output amplitude is the amplitude of this fundamental component of the signal and does not include any contribution from harmonics of the input signal. This smooths the discontinuities because the sinewave excites a range of input levels, including both linear regions and discontinuities. In other words the sinewave input spans a plurality of the gain steps indicated in FIG. 4 and thus generates additional harmonic components in the output.

FIG. 6 shows a graph of instantaneous signal level against time for an input signal 602 to compressor 204 and an output signal 604 from compressor 204 for a 60 Hz sinewave input at −24 dB relative to a full-scale output level. Curve 604 indicates the effect of step changes in the compressor's gain as the instantaneous input signal level changes. The discontinuities,in curve 604 generate harmonics of the input signal to the compressor, which are perceived as an enhancement in the level of bass energy. These discontinuities are preferably) smoothed by low-pass filter 208 to reduce any high frequency distortion that might otherwise be perceived.

The operation of the limiting mode of the compressor will next be described. The aim of the limiting mode is to prevent the output of the bass boost circuit reaching a hard limit of the digital word used to represent the boosted signal, and thus to prevent overload. The limit detector 316 establishes when high level signals occur at the output of the bass compressor (for example on line 214a or line 214b), in a preferred embodiment detecting when the output signal level reaches −2.5 dB.

When such a limit condition is detected by limit detector 316 an output on line 314 controls multiplexer 310 to select a k-value of −1 for output on line 302 to left shift gain block 304. In response to this input (−1) gain block 304 performs a single right shift (rather than left shifts) the signal on line 202, to attenuate the output on line 205. This does not generate too large a discontinuity in the output signal because limiting only occurs when the input word is close to full-scale, resulting in a value of k=0 in the compressor immediately prior to limiting.

An alternative and more general implementation of a limiting function may be provided by subtracting a value, such as 1, from the compression factor F when a limit condition is detected.

The coarse approximations used in compressor 204, and the limiter if implemented, introduce harmonic distortion. This is preferably filtered by low-pass filter 208 to ensure that only low frequency harmonics are present in the output signal. These harmonics are not significantly audible as distortion but add to the perceived level of bass in the output signal from the bass compressor circuit 200.

The bass compressor circuit 200 may also be operated in an expander mode if gain block 210 is configured to provide negative gain. In embodiments the compressor 204 is disablable so that the circuit 200 provides a bass cut, with larger negative values of the gain C of gain block 210 resulting in increased base cut. Additionally or alternatively however compressor 204 may be enabled, and in this case the overall negative gain through the compressor 204, low-pass filter 208 and gain block 210 is greater for low amplitude signals than for high amplitude signals. As a result bass compressor 200 provides more cut for low amplitude signals than for high amplitude signals, resulting in dynamic range expansion over bass frequencies.

In a further alternative embodiment an expansion function may be provided by substituting a variable right shift power-of-two gain block for variable left shift gain block 304. With this arrangement the circuit provides greater attenuation of low amplitude signals than of high amplitude signals and again provides dynamic range expansion for bass frequency signals, such as signals below 150 Hz and preferably below 100 Hz.

The preferred embodiment of bass compressor 200 illustrated in FIG. 2 particularly advantageous for mid-fidelity, typically portable systems where high perceived levels of bass are appreciated by listeners but reference quality is not needed.

Where higher levels of signal quality are desirable compressor 204 may be arranged to reduce the discontinuities in the output signals whilst still providing some non-linearity for bass enhancement. In such an embodiment MSB detector 306 may be configured to provide a finer resolution output than that previously described, for example by using a signal level detector which is able to resolve finer changes in signal level than those described above based upon MSB bit position. With such an arrangement the value of k provided on output 302 to gain block 304 has an increased number of gradations and thus gain block 304 is preferably implemented using a multiplier. The, number of bits resolution on output 302 then determines the output signal quality, improved quality being provided by a greater number of bits.

The above-described bass compressor provides a number of benefits. The use of instantaneous compression rather than compression based upon a long-term average of input signal level facilitates introduction of the desired distortion. It also provides improved loudness compensation, dependent upon instantaneous signal level rather than on the setting of a volume control per se, and is thus responsive to the content of audio programme material processed by the compressor. Embodiments of non-linear compressor 204 have lower complexity than prior art compressors. It is also straightforward to include an overload limiter, using feedback from an output stage of the compressor. By filtering the output of compressor 204 audible distortion, that is a change to the audio signal perceived as distortion by the human ear, can be reduced to insignificant levels and residual signal distortion is perceived not as audible distortion but rather as an increase in the energy of the audio signal at bass frequencies. Furthermore, embodiments of the bass compressor can provide a dynamic range expansion function when the distorted, compressed audio signal is subtracted from rather than added to the original signal.

No doubt many effective alternatives will occur to the skilled person and it will be understood that the invention is not limited to the described embodiments and encompasses modifications apparent to those skilled in the art lying within the spirit and scope of the claims appended hereto.

1. Apparatus for altering a perceived level of bass in an audio signal, the apparatus comprising:
an audio input to receive an audio input signal;
a compressor coupled to the audio input and having an output, to compress said audio input signal;
a high-cut filter coupled to the output of said compressor to provide a filtered compressor output; and
a combiner to combine a signal from said compressor output with a signal from said audio input to provide a combined audio output; and
wherein said compressor is configured to distort said audio input signal such that said distortion is perceivable as an increase in the level of bass in said combined audio output.

2. Apparatus as claimed in claim 1 wherein said compressor is configured to perform a non-linear operation using substantially instantaneous levels of said audio input signal.

3. Apparatus as claimed in claim 2 wherein said non-linear operation comprises at least one step change in compressor gain dependent upon a substantially instantaneous level of signal input to said compressor.

4. Apparatus as claimed in claim 3 wherein said non-linear operation comprises a plurality of step changes in compressor gain at points dependent upon substantially instantaneous levels of signal input to said compressor.

5. Apparatus as claimed in claim 1 further comprising limiting means responsive to a signal level dependent upon the output of said compressor to limit or reduce said combined audio output.

6. Apparatus as claimed in claim 1 for enhancing the perceived level of bass in an audio signal, wherein said combiner comprises an additive combiner.

7. Apparatus as claimed in claim 1 wherein said audio input signal comprises a digital audio input signal and said compressor comprises a digital compressor.

8. Apparatus as claimed in claim 7 wherein said compressor has an input and comprises a gain selector and a multiplier both coupled to said compressor input, said multiplier being responsive to said gain selector.

9. Apparatus as claimed in claim 8 wherein said multiplier comprises a left shifter.

10. Apparatus as claimed in claim 8 wherein said gain selector comprises a most significant bit detector to detect a most significant set bit of a compressor input signal and to provide a digital output value for said multiplier.

11. Apparatus as claimed in claim 10 wherein said gain selector further comprises a divider to reduce said digital output value for said multiplier.

12. Apparatus as claimed in claim 11 wherein said divider comprises a right shifter.

13. Apparatus as claimed in claim 8 wherein said gain selector comprises a look-up table.

14. A non-linear, instantaneous digital compressor comprising:
an input;
a gain selector coupled to said input; and
a variable left shifter coupled to said input and responsive to said gain selector to apply a variable gain to a digital signal on said input responsive to an instantaneous level of said digital signal.

15. A method of altering a perceived level of bass in an audio signal, the method comprising:
compressing and distorting the audio signal to provide a compressed and distorted signal in which the distortion is perceivable as an increase in the level of bass of the signal;
low-pass filtering said compressed and distorted signal; and
combining said audio signal with said filtered compressed and distorted signal to provide an output signal with an altered perceived level of bass.

16. A method as claimed in claim 15 wherein said compressing provides said distorting.

17. A method as claimed in claim 16 wherein said compressing comprises varying a substantially instantaneous gain applied to said audio signal responsive to a substantially instantaneous value of said audio signal.

18. A method as claimed in claim 17 wherein said varying comprises altering said gain in one or more discrete steps.

19. A method as claimed in claim 17 wherein said audio signal comprises a digital audio signal and said gain varying comprises varying a left shift applied to said audio signal.

20. A method as claimed in claim 17 wherein said compressing further comprises selecting a gain for said audio signal responsive to a substantially instantaneous value of said audio signal.

21. A method as claimed in claim 20 wherein said audio signal comprises a digital audio signal and said selecting responsive to a substantially instantaneous value of said audio signal comprises detecting a most significant bit (MSB) of said digital audio signal.

22. A method as claimed in claim 21 wherein said MSB detecting comprises looking up a value of said digital audio signal in a look-up table.

23. A method as claimed in claim 15 wherein said output signal comprises a digital output signal, the method further comprising controlling a level of said digital output signal to substantially prevent said output signal level exceeding an upper limit imposed by a digital representation of said output signal.

24. A method as claimed in claim 23 wherein said controlling comprises detecting a limit condition and controlling a gain applied by said compressor in response to said detecting.

25. Processor control code to, when running, implement the compressor of claim 15,

26. A carrier carrying the processor control code of claim 25.

27. Processor control code to, when running, implement the method of claim 15.

28. A carrier carrying the processor control code of claim 27.
